(19) United States
(12) Patent Application Publication
(10) Pub. No.: US 2025/0372951 A1
(43) Pub. Date: Dec. 4, 2025

(54) OPTICAL DEVICE AND WAVELENGTH-TUNABLE LASER

(71) Applicant: FURUKAWA ELECTRIC CO., LTD., Tokyo (JP)

(72) Inventors: Kazuki YAMAOKA, Tokyo (JP); Maiko ARIGA, Tokyo (JP)

(73) Assignee: FURUKAWA ELECTRIC CO., LTD., Tokyo (JP)

(21) Appl. No.: 19/303,954

(22) Filed: Aug. 19, 2025

Related U.S. Application Data
(63) Continuation of application No. PCT/JP2025/003479, filed on Feb. 3, 2025.

(30) Foreign Application Priority Data
Feb. 6, 2024 (JP) 2024-016581

(51) Int. Cl. H01S 5/14; H01S 5/024; H01S 5/06

(52) U.S. Cl. CPC H01S 5/141; H01S 5/02415; H01S 5/0612

(57) ABSTRACT

An optical device includes: a base; a plurality of optical components fixed to the base, the plurality of optical components including an etalon filter; and a heater wiring layer provided at a location away from a light passing region on a surface of the etalon filter and configured to generate heat from electric current flow.

This application is a continuation of International Application No. PCT/JP2025/003479, filed on Feb. 3, 2025 which claims the benefit of priority of the prior Japanese Patent Application No. 2024-016581, filed on Feb. 6, 2024, the entire contents of which are incorporated herein by reference.

### BACKGROUND

The present disclosure relates to an optical device and a wavelength-tunable laser.

An on-chip integrated wavelength-tunable laser is known (Japanese Patent No. 2687464). In the wavelength-tunable laser according to Japanese Patent No. 2687464, an amplification unit that emits and amplifies light and an optical filter having predetermined wavelength characteristics are integrated.

### SUMMARY

In the configuration of Japanese Patent No. 2687464, there is a risk that the wavelength characteristics of the optical filter may be affected, for example, when the amount of current to the amplification unit is increased to enhance the output of the laser, and heat generated in the amplification unit is transferred to the optical filter. Therefore, it is preferable that the temperature of the optical filter may be adjusted separately. In addition, at that time, it is preferable that the temperature of the optical filter may be adjusted more accurately.

There is a need for an improved novel optical device and a wavelength-tunable laser capable of adjusting the temperature of the optical filter separately and more accurately.

According to one aspect of the present disclosure, there is provided an optical device including: a base; a plurality of optical components fixed to the base, the plurality of optical components including an etalon filter; and a heater wiring layer provided at a location away from a light passing region on a surface of the etalon filter and configured to generate heat from electric current flow.

According to another aspect of the present disclosure, there is provided a wavelength-tunable laser including: a light amplification unit configured to generate and amplify light and output the light from a first end and a second end on an opposite side from the first end; a first mirror configured to reflect the light output from the first end; a second mirror configured to reflect the light output from the second end; an etalon filter provided between the light amplification unit and the first mirror or the second mirror, the etalon filter having a predetermined wavelength characteristic and being configured to allow the light output from the light amplification unit to pass therethrough; and a heater wiring layer provided at a location away from a light passing region on a surface of the etalon filter and configured to generate heat from electric current flow.

### BRIEF DESCRIPTION OF THE DRAWINGS

FIG. 1 is an exemplary schematic plan view illustrating a state in which an upper lid of an optical device according to a first embodiment is removed;

FIG. 2 is an exemplary schematic side view of a part of the optical device according to the first embodiment;

FIG. 3 is an exemplary schematic front view of an etalon filter included in the optical device according to the first embodiment;

FIG. 4 is an exemplary schematic plan view illustrating a state in which an upper lid of an optical device according to a second embodiment is removed;

FIG. 5 is an exemplary schematic plan view illustrating a state in which an upper lid of an optical device according to a third embodiment is removed;

FIG. 6 is an exemplary schematic plan view illustrating a state in which an upper lid of an optical device according to a fourth embodiment is removed;

FIG. 7 is an exemplary schematic plan view illustrating a state in which an upper lid of an optical device according to a fifth embodiment is removed;

FIG. 8 is an exemplary schematic side view of a part of the optical device according to the fifth embodiment;

FIG. 9 is an exemplary schematic plan view illustrating a state in which an upper lid of an optical device according to a sixth embodiment is removed;

FIG. 10 is an exemplary schematic plan view illustrating a state in which an upper lid of an optical device according to a seventh embodiment is removed;

FIG. 11 is an exemplary schematic plan view illustrating a state in which an upper lid of an optical device according to an eighth embodiment is removed;

FIG. 12 is an exemplary schematic plan view illustrating a state in which an upper lid of an optical device according to a ninth embodiment is removed;

FIG. 13 is an exemplary schematic plan view illustrating a state in which an upper lid of an optical device according to a tenth embodiment is removed;

FIG. 14 is an exemplary schematic front view of an etalon filter included in an optical device according to an eleventh embodiment;

FIG. 15 is an exemplary schematic front view of an etalon filter included in an optical device according to a twelfth embodiment;

FIG. 16 is an exemplary schematic front view of an etalon filter included in an optical device according to a thirteenth embodiment;

FIG. 17 is an exemplary schematic front view of an etalon filter included in an optical device according to a fourteenth embodiment;

FIG. 18 is an exemplary schematic front view of an etalon filter included in an optical device according to a fifteenth embodiment;

FIG. 19 is an exemplary schematic front view of an etalon filter included in an optical device according to a sixteenth embodiment;

FIG. 20 is an exemplary schematic front view of an etalon filter included in an optical device according to a seventeenth embodiment;

FIG. 21 is an exemplary schematic front view of an etalon filter included in an optical device according to an eighteenth embodiment;

FIG. 22 is an exemplary schematic perspective view of an etalon filter included in an optical device according to a nineteenth embodiment;

FIG. 23 is an exemplary schematic front view of an etalon filter included in an optical device according to a twentieth embodiment;

FIG. 24 is an exemplary schematic front view of an etalon filter included in an optical device according to a twenty-first embodiment;

FIG. 25 is an exemplary schematic front view of an etalon filter included in an optical device according to a twenty-second embodiment;

FIG. 26 is an exemplary schematic perspective view of an etalon filter included in an optical device according to a twenty-third embodiment;

FIG. 27 is an exemplary schematic front view of a modification of the etalon filter included in the optical device according to the embodiment;

FIG. 28 is an exemplary schematic front view of a modification of the etalon filter included in the optical device according to the embodiment;

FIG. 29 is an exemplary schematic rear view of a modification of the etalon filter included in the optical device according to the embodiment;

FIG. 30 is an exemplary schematic rear view of a modification of the etalon filter included in the optical device according to the embodiment;

FIG. 31 is an exemplary schematic rear view of a modification of the etalon filter included in the optical device according to the embodiment; and

FIG. 32 is an exemplary schematic rear view of a modification of the etalon filter included in the optical device according to the embodiment.

### DETAILED DESCRIPTION

Hereinafter, exemplary embodiments are disclosed. The configurations of the embodiments described below, and the functions and results (effects) produced by the configurations are examples. The present disclosure may also be realized by configurations other than those disclosed in the following embodiments. In addition, according to the present disclosure, it is possible to obtain at least one of various effects (including derivative effects) obtained by the configurations.

A plurality of embodiments described below have the same configuration. Therefore, according to the configuration of each embodiment, the same function and effect based on the same configuration may be obtained. In addition, in the following description, the same configuration is given the same reference numeral and redundant description may be omitted.

In addition, in the present specification, ordinal numbers may be given for convenience to distinguish components, members, portions, directions, light, and the like. The ordinal number does not indicate the priority or order, and does not specify the number.

In each drawing, an X direction is represented by an arrow X, a Y direction is represented by an arrow Y, and a Z direction is represented by an arrow Z. The X direction, the Y direction, and the Z direction intersect each other and are orthogonal to each other.

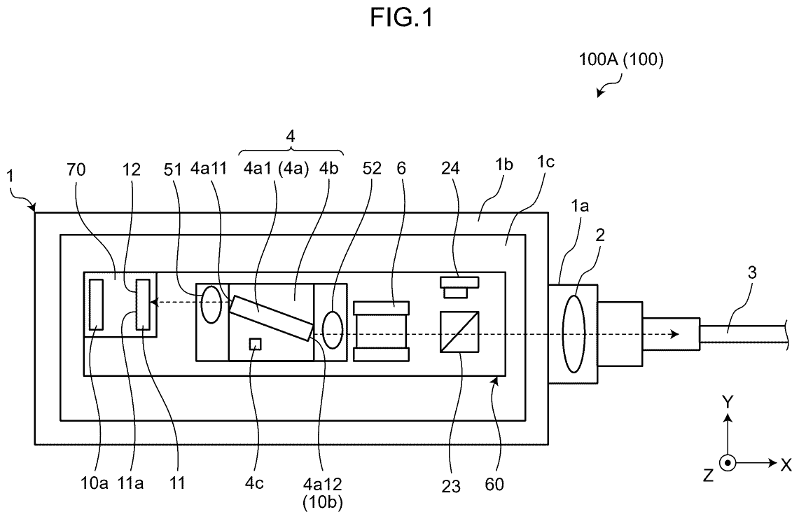

FIG. 1 is a plan view illustrating a state in which an upper lid of an optical module 100A (100) according to a first embodiment is removed. The optical module 100A (100) is an example of an optical device including a wavelength-tunable laser.

As illustrated in FIG. 1, the optical module 100A includes a housing 1. The housing 1 includes an output port 1a, four side walls 1b, a bottom wall 1c, and an upper lid (not illustrated).

The bottom wall 1c is a plate-shaped member located at an end in the opposite direction of the Z direction. The bottom wall 1c intersects with and is orthogonal to the Z direction, has a substantially constant thickness in the Z direction, and extends in the X direction and the Y direction. The bottom wall 1c is made of a material having high thermal conductivity, such as copper tungsten (CuW), copper molybdenum (CuMo), or aluminum oxide (Al₂O₃).

The side walls 1b are each a plate-shaped member. In addition, the side walls 1b are each substantially orthogonal to the bottom wall 1c and orthogonal to the X direction or the Y direction, and extend in the Z direction.

The output port 1a is provided on the side wall 1b located at the end in the X direction. A lens 2 is accommodated in the output port 1a. The output port 1a supports an optical fiber 3 that outputs output light to an outside.

The upper lid is a plate-shaped member located at an end in the Z direction. The upper lid intersects with and is orthogonal to the Z direction, has a substantially constant thickness in the Z direction, and extends in the X direction and the Y direction. The upper lid is substantially parallel to the bottom wall 1c.

The output port 1a, the side wall 1b, and the upper lid are made of a material having a low thermal expansion coefficient, such as an Fe—Ni—Co alloy or aluminum oxide (Al₂O₃).

An accommodation chamber in the housing 1 is, for example, hermetically sealed. For example, inert gas such as nitrogen gas may be accommodated in the housing 1. In this case, nitrogen gas is an example of gas.

Components such as a chip-on-submount 4, lenses 51 and 52, an etalon filter 11, a mirror 10a, an optical isolator 6, a beam splitter 23, a photodiode 24, and a carrier 60 are accommodated in the housing 1. These components are fixed to the housing 1 directly or indirectly via other members, components, or the like. Among these components, the chip-on-submount 4, the lenses 51 and 52, the mirror 10a, the etalon filter 11, the optical isolator 6, the beam splitter 23, and the photodiode 24 are examples of optical components. The optical component is, for example, a component that outputs light, receives light, transmits light, or acts on light. Note that optical components other than the above-described components, and components such as electronic components and electric components different from the optical components may be accommodated and supported in the housing 1. The housing 1 is an example of a base.

In addition, in the present embodiment, the chip-on-submount 4, the lenses 51 and 52, the etalon filter 11, the mirror 10a, the optical isolator 6, the beam splitter 23, and the photodiode 24 are supported on the carrier 60 directly or indirectly via other members. The carrier 60 is, for example, a Peltier module having a temperature adjustment function. In this case, the carrier 60 is an example of a temperature adjustment mechanism capable of adjusting the temperature of a laser element 4a. The Peltier module will be described in detail later. Note that, for example, a temperature adjustment mechanism different from the Peltier module, such as a heater as a resistance heating module, may be provided so as to correspond to the chip-on-submount 4.

The chip-on-submount 4 includes a laser element 4a, a submount 4b, and a thermistor 4c. The laser element 4a is a semiconductor laser element. The laser element 4a includes a light amplification unit 4a1. The chip-on-submount 4 may also be referred to as a light-emitting unit.

The light amplification unit 4a1 has a laser medium such as a semiconductor active layer, and amplifies light while generating light according to a supplied current. The light amplification unit 4a1 outputs light from one end 4a11 and another end 4a12 on the opposite side from the one end 4a11. The end 4a11 is an example of a first end, and the end 4a12 is an example of a second end.

The end 4a12 is provided with a mirror 10b. The mirror 10b reflects at least a part of incoming light. In the present embodiment, the mirror 10b reflects a part of light output from the light amplification unit 4a1 and inputs the light to the light amplification unit 4a1, while transmitting a part of the light output from the light amplification unit 4a1. The mirror 10b is, for example, a dielectric multi-layer mirror. The mirror 10b is an example of a second mirror.

The submount 4b supports the laser element 4a. The submount 4b is made of an insulating material having high thermal conductivity. The thermistor 4c is an example of a temperature sensor. The thermistor 4c is mounted on the submount 4b, for example.

The light output from the end 4a11 of the light amplification unit 4a1 passes through the lens 51. The lens 51 is, for example, a collimating lens.

The light having passed through the lens 51 reaches the mirror 10a via the etalon filter 11.

The etalon filter 11 has predetermined wavelength characteristics and transmits light of a wavelength corresponding to the wavelength characteristics. A heater 12 is provided on an end surface 11a of the etalon filter 11. The heater 12 changes the optical path length of the etalon filter 11, thereby making it possible to change the wavelength characteristics of the etalon filter 11. The heater 12 will be described later in detail.

The mirror 10a reflects at least a part of incoming light. In the present embodiment, the mirror 10a reflects all the light having come to the mirror 10a so as to return it to the etalon filter 11. The mirror 10a is, for example, a dielectric multi-layer mirror. The mirror 10a is an example of a first mirror.

The light output from the end 4a12 of the light amplification unit 4a1 and having passed through the mirror 10b reaches the optical isolator 6 via the lens 52. The lens 52 is, for example, a collimating lens.

The optical isolator 6 transmits the incoming light, in this case, the light having come from the lens 52 toward the beam splitter 23 and blocks light returning from the beam splitter 23.

The beam splitter 23 outputs most of the light to the lens 2 and outputs a part of the light to the photodiode 24. The lens 2 condenses the light from the beam splitter 23 and couples the light to the optical fiber 3.

The photodiode 24 receives the light from the beam splitter 23 and outputs a detection signal corresponding to received optical intensity. The detection signal is input to a controller (not illustrated) via a wiring (not illustrated). The controller controls the operation of the laser element 4a based on the detection signal from the photodiode 24.

In this configuration, the light amplification unit 4a1 and the etalon filter 11 are interposed between the mirror 10a and the mirror 10b, forming a resonance mechanism in which light reciprocates at a predetermined wavelength and resonates between the mirror 10a and the mirror 10b. In the resonance mechanism, the resonant wavelength may be changed by changing the optical path length by changing the temperature of the etalon filter 11.

In addition, in this configuration, the lens 51 is provided between the laser element 4a and the etalon filter 11, thereby making it possible to secure a longer distance between the light amplification unit 4a1 of the laser element 4a and the etalon filter 11. The light amplification unit 4a1 generates heat due to its operation. Therefore, if the distance between the light amplification unit 4a1 and the etalon filter 11 is short, there is a risk that temperature adjustment of the etalon filter 11 by the heater 12 may be unlikely to be performed more accurately due to the heat generated at the light amplification unit 4a1. In this regard, in the present embodiment, the lens 51 is provided to secure a longer distance between the light amplification unit 4a1 and the etalon filter 11. Therefore, the thermal influence of the light amplification unit 4a1 on the etalon filter 11 may be suppressed, and thus the temperature adjustment of the etalon filter 11 by the heater 12 and thus wavelength control may be performed more accurately.

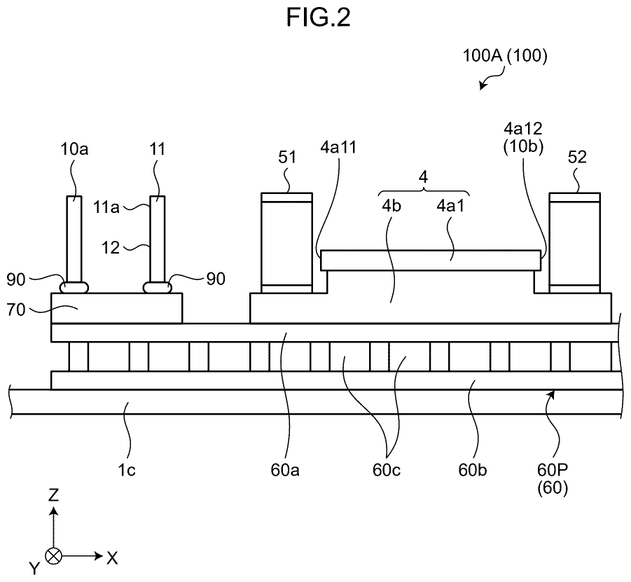

FIG. 2 is a side view of a part of the optical module 100A. As described above, in the present embodiment, the carrier 60 is configured as the Peltier module 60P. As illustrated in FIG. 2, the Peltier module 60P includes a first substrate 60a, a second substrate 60b, and a plurality of thermoelectric elements 60c. The thermoelectric element 60c is a columnar semiconductor device provided between the first substrate 60a and the second substrate 60b. The thermoelectric element 60c is made of a P-type semiconductor or an N-type semiconductor, for example, a bismuth tellurium semiconductor. The plurality of thermoelectric elements 60c are connected in series in a state where PN junction is formed by a wiring pattern (not illustrated) provided on the first substrate 60a and the second substrate 60b. Then, when power is supplied from a wiring (not illustrated) to a circuit including the plurality of thermoelectric elements 60c connected in series via the wiring pattern, the Peltier module 60P absorbs or generates heat according to the direction of the current of the power. The Peltier module 60P may adjust the temperature of the laser element 4a according to, for example, a detection value by the thermistor 4c, and is an example of the temperature adjustment mechanism.

In the present embodiment, the etalon filter 11, the heater 12, and the mirror 10a are supported by the Peltier module 60P via the housing 1, the Peltier module 60P, and a heat shielding member 70 having a thermal conductivity lower than that of a metal material or the like. In other words, the heat shielding member 70 is interposed between the etalon filter 11, the heater 12, and the mirror 10a and the light amplification unit 4a1 or the Peltier module 60P, and suppresses thermal conduction therebetween. The heat shielding member 70 is made of, for example, glass. The etalon filter 11 and the mirror 10a are fixed on the heat shielding member 70 by, for example, a bonding material 90. According to this configuration, it is possible to suppress a decrease in the accuracy of the temperature adjustment function of the heater 12 for the etalon filter 11 due to heat from the Peltier module 60P associated with the temperature adjustment and heat transferred from the light amplification unit 4a1 via the Peltier module 60P. Note that the heat shielding member 70 is in a block shape, but is not limited thereto. For example, the heat shielding member 70 may be provided with a hollow portion.

The etalon filter 11 and the mirror 10a are supported on the Peltier module 60P together with the chip-on-submount 4 and the lenses 51 and 52. According to this configuration, it is possible to suppress a decrease in coupling efficiency between these optical components, for example, even when the relative positional relationship between the optical components changes due to the temperature adjustment function by the Peltier module 60P.

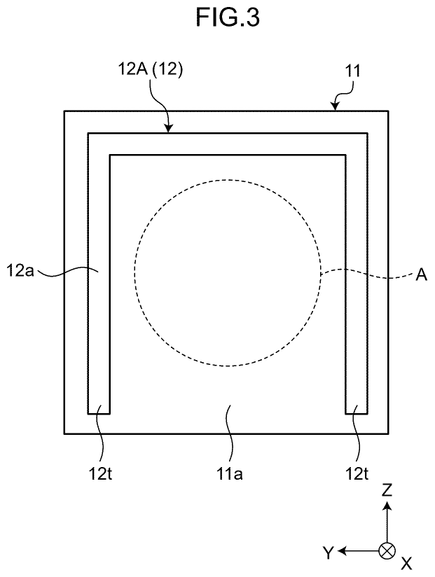

FIG. 3 is a front view of the etalon filter 11. The etalon filter 11 includes a body having end surfaces formed as planes parallel to each other, and a reflection film formed on each end surface and reflecting light with a predetermined reflectivity. The body is made of, for example, glass or silicon.

The heater 12A (12) is provided on an end surface 11a as a surface of the etalon filter 11. Note that, in each drawing, reference numeral 11a is given only to the end surface on which the heater 12 is provided.

The heater 12 includes two ends 12t and 12t and an extending portion 12a. The extending portion 12a extends while bending with a predetermined width and thickness (height) on the end surface 11a between the two ends 12t and 12t. In the present embodiment, the extending portion 12a extends substantially along a peripheral edge of the etalon filter 11 in an inverted U shape opened in the opposite direction of the Z direction. The heater 12 is an example of a heater wiring layer and may also be referred to as a resistance heating layer.

The heater 12 is formed directly on the end surface 11a as the surface of the etalon filter 11 by, for example, vapor deposition, sputtering, or the like. With this configuration, as compared with a configuration in which the heater is attached to the etalon filter 11 via a bonding material, and a configuration in which another member provided with the heater is attached to the etalon filter 11, that is, a configuration in which the heater is attached to the etalon filter 11 via another member, the heater 12 may heat the etalon filter 11 more efficiently and more quickly, thus making it possible to control the temperature of the etalon filter 11 and the wavelength of light more accurately. In addition, the responsiveness of wavelength control may also be further enhanced.

Since the heater 12 is opaque, it is provided at a location away from a light passing region A on the end surface 11a of the etalon filter 11. The light passing region A may be defined as, for example, a region where the intensity is 1/e2 or more of the maximum intensity. With this configuration, it is possible to suppress the heater 12 from interfering with the traveling of light. In addition, the heater 12 extends so as to surround the passing region A at least partially while bending on the end surface 11a. With this configuration, it is possible to heat a wider range of the end surface 11a of the etalon filter 11, specifically, a wider range around the passing region A, and to reduce a temperature difference (temperature unevenness) depending on a location as compared with a case where the etalon filter 11 is locally heated, thus making it possible to control the wavelength of light more accurately.

The specifications such as the material, length, width, and thickness of the heater 12 are determined so as to obtain heating performance required for the etalon filter 11 according to the range of controlling the wavelength of light. As an example, in a case where the optical module 100A is used as the wavelength-tunable laser, the specifications of the heater 12 are set such that the heater 12 may heat at least the passing region A of the etalon filter 11 to 150 [° C.], and may change at least the temperature of the passing region A of the etalon filter 11 in a range of, for example, room temperature or more and 150 [° C.] or less by changing supplied power. The heater 12 may have a stacked structure made of a material that generates heat from electric current flow, that is, any of Ti, Pt, Au, Ni, Ta2N, TiW, and indium tin oxide, or a material containing any of them. Specifically, the heater 12 may be formed as a film including a stacked structure of any of Ti/Pt/Au, Ti/Pt, Ti/Pt/Ni, and Ti/Pt/Ta2N, for example. Furthermore, the width of the heater 12 is, for example, 0.5 [mm] or more and 2.0 [mm] or less, and the thickness of the heater 12 is, for example, 0.05 [mm] or more and 0.3 [mm] or less.

The heater 12 may be used for temperature detection. For example, when the heater 12 is made as a film including a Ti/Pt stacked structure, a resistance value of the heater. 12 easily changes in response to a temperature change. In this case, the temperature of the heater 12 and thus the temperature of the etalon filter 11 may be detected by measuring the resistance value. The heater 12 used for temperature detection in this manner is an example of a resistance temperature-measuring wiring layer.

As described above, in the present embodiment, the heater 12(d) is provided directly on the etalon filter 11. Therefore, the temperature of the etalon filter 11 may be adjusted by the heater 12 separately and more accurately. In addition, in the present embodiment, the heater 12 is provided at the location away from the light passing region A on the end surface 11a (surface) of the etalon filter 11. Therefore, it is possible to obtain the effect of making it easier to enhance the control accuracy and the control responsiveness of the wavelength, while suppressing the light from being blocked by the heater 12.

In addition, the heater 12 has a bent portion on the end surface 11a and extends so as to surround the passing region A at least partially. According to this configuration, the length of the heater 12 is easily increased, and thus the desired heating performance by the heater 12 is easily secured.

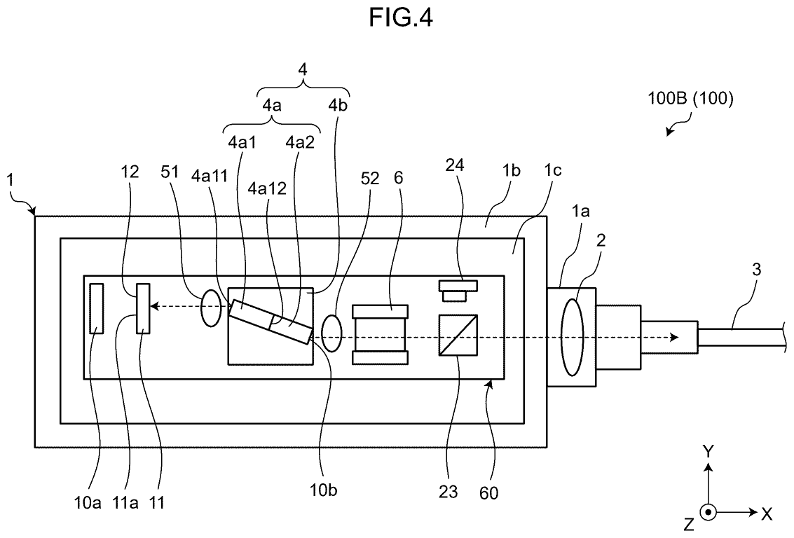

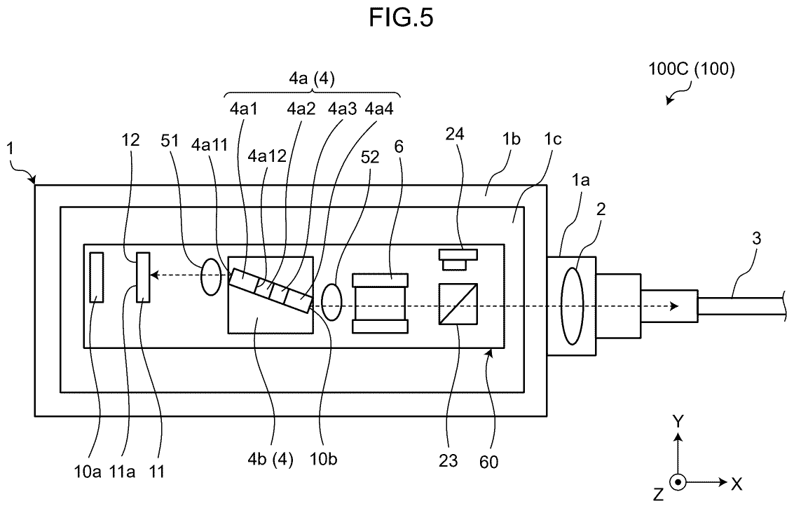

FIG. 4 is a plan view illustrating a state in which an upper lid of an optical module 100B (100) according to a second embodiment is removed. In addition, FIG. 5 is a plan view illustrating a state in which an upper lid of an optical module 100C (100) according to a third embodiment is removed. As illustrated in FIG. 4, in the optical module 100B, the laser element 4a includes an optical filter 4a2 together with the light amplification unit 4a1. In addition, as illustrated in FIG. 5, in the optical module 100C, the laser element 4a includes optical filters 4a2 and 4a3 and a semiconductor optical amplifier (SOA) 4a4 together with the light amplification unit 4a1. The optical filters 4a2 and 4a3 are, for example, a distributed bragg reflector (DBR), a ring filter, a phase adjustment filter, a Mach-Zehnder filter, or the like. Also when the laser element 4a includes one or more optical functional units other than the light amplification unit 4a1 in this manner, the same effects as those of the above-described first embodiment may be obtained. In addition, it is possible to obtain the advantage that the optical module 100 may be configured more compactly as compared with a case where the optical function units are separately provided.

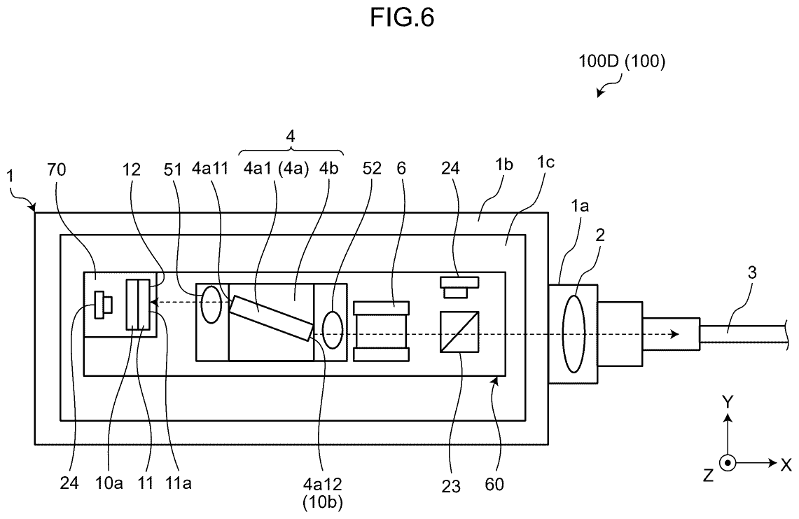

FIG. 6 is a plan view illustrating a state in which an upper lid of an optical module 100D (100) according to a fourth embodiment is removed. As illustrated in FIG. 6, in the optical module 100D, the etalon filter 11 and the mirror 10a are integrated. The mirror 10a is, for example, a dielectric multi-layer mirror. The heater 12 is provided on the end surface 11a on the opposite side from the mirror 10a. Also with this configuration, the same effects as those of the above-described first embodiment may be obtained. In addition, according to this configuration, since the etalon filter 11 and the mirror 10a are integrated, the optical module 100 may be configured more compactly, thus obtaining the advantage that a space for arranging other components such as a photodiode 24 may be easily secured.

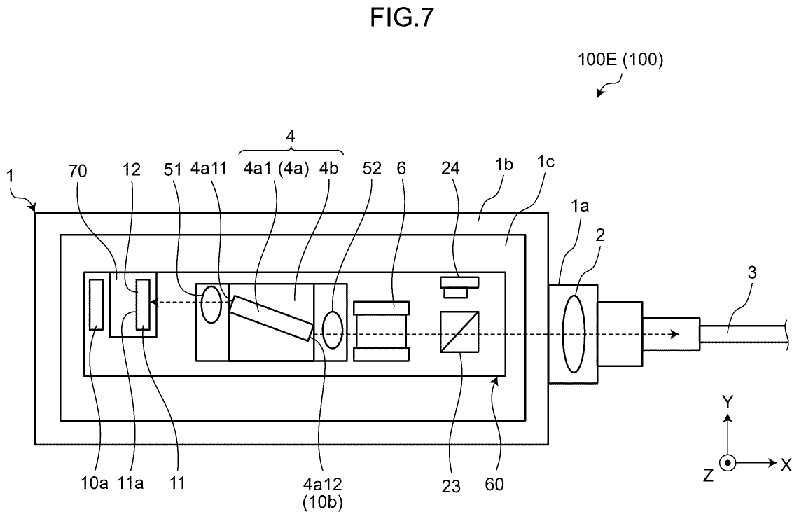

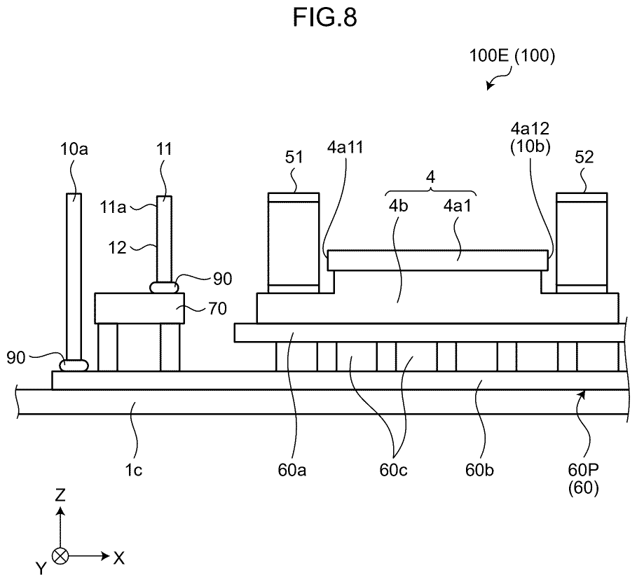

FIG. 7 is a plan view illustrating a state in which an upper lid of an optical module 100E (100) according to a fifth embodiment is removed. In addition, FIG. 8 is a side view of a part of the optical module 100E. As illustrated in FIGS. 7 and 8, in the optical module 100E, only the etalon filter 11 is attached onto the heat shielding member 70. As illustrated in FIG. 8, the heat shielding member 70 may have a beam structure. By adopting the beam structure, it is possible to reduce the cross-sectional area of the thermal conduction path on the heat shielding member 70, and to further enhance the heat shielding performance. According to the present embodiment, it is possible to obtain the same effects as those of the above-described first embodiment, and to obtain the advantage that the heat shielding member 70 may be configured to be smaller.

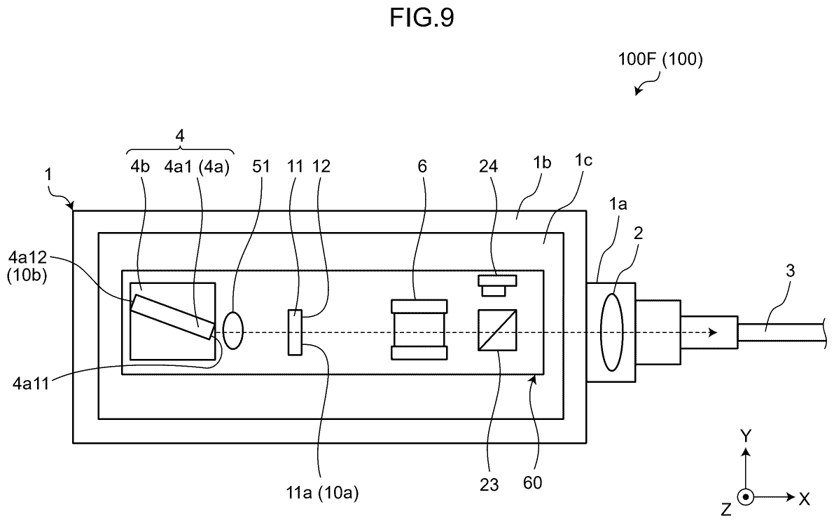

FIG. 9 is a plan view illustrating a state in which an upper lid of an optical module 100F (100) according to a sixth embodiment is removed. As illustrated in FIG. 9, the optical module 100F includes one etalon filter 11 between the lens 51 and the optical isolator 6. In addition, the mirror 10b is provided at the end 4a12 of the light amplification unit 4a1, and the mirror 10a is provided on the end surface 11a of the etalon filter 11 on the opposite side from the lens 51. Also with this configuration, the same effects as those of the above-described first embodiment may be obtained. Note that the heater 12 is provided on the end surface 11a on which the mirror 10a is provided, but may be provided on the opposite end surface on which the mirror 10a is not provided.

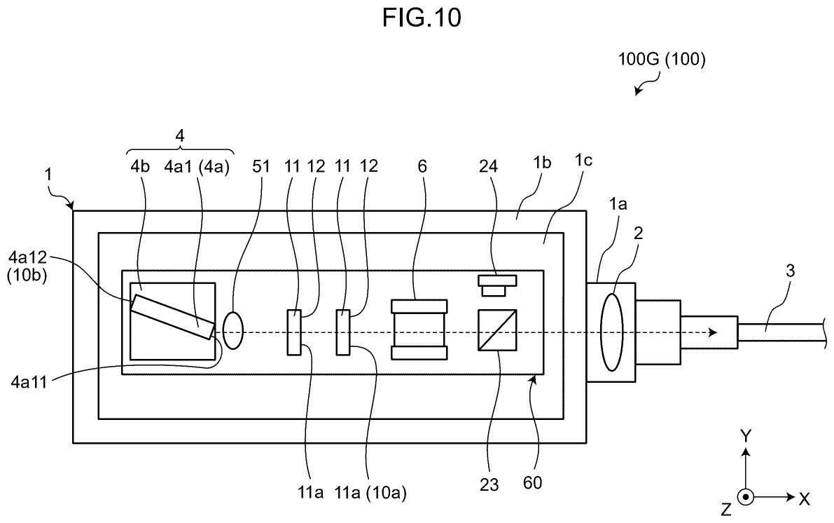

FIG. 10 is a plan view illustrating a state in which an upper lid of an optical module 100G (100) according to a seventh embodiment is removed. As illustrated in FIG. 10, the optical module 100G includes two etalon filters 11 in series between the lens 51 and the optical isolator 6. In addition, the mirror 10b is provided at the end 4a12 of the light amplification unit 4a1, and the mirror 10a is provided on the end surface 11a on the opposite side from the lens 51 of the etalon filter 11 on a side far from the lens 51. The heater 12 is provided on the end surface 11a of each etalon filter 11 far from the lens 51. Also with this configuration, the same effects as those of the above-described first embodiment may be obtained. In addition, according to this configuration, since the number of etalon filters 11 is large, it is possible to obtain the advantage that a controllable wavelength bandwidth may be increased. Note that the heater 12 may be provided on an end surface of the etalon filter 11 on a side close to the lens 51.

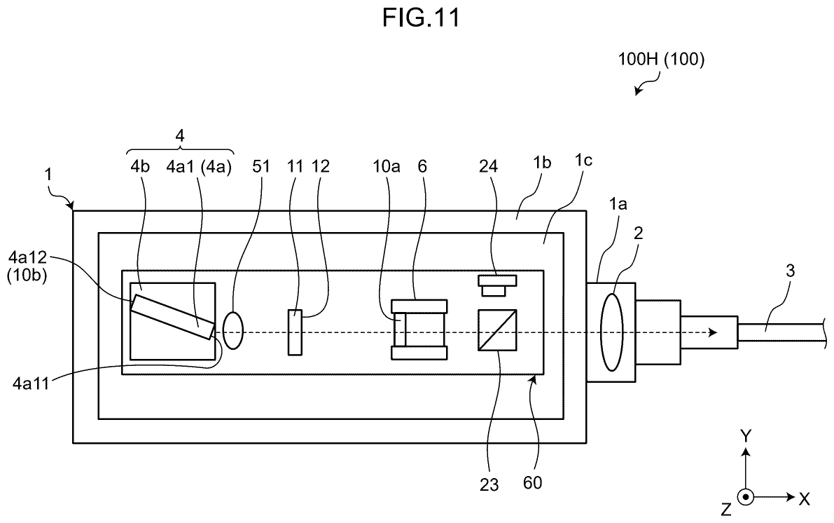

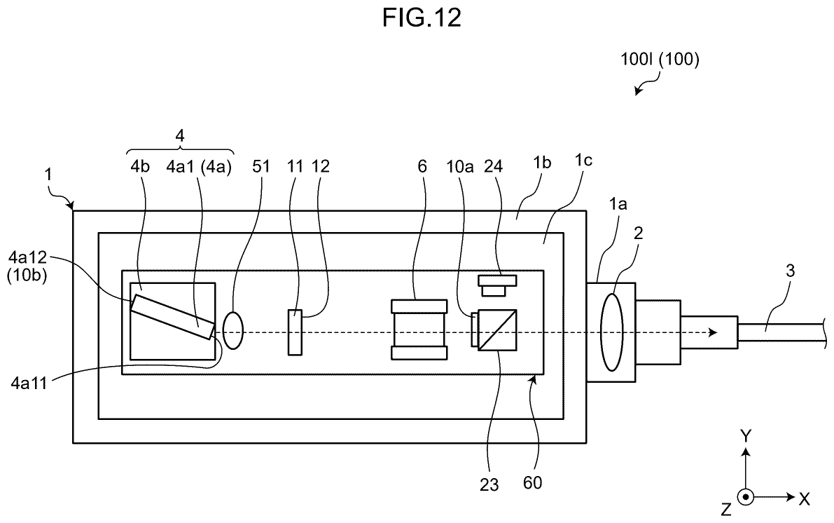

FIG. 11 is a plan view illustrating a state in which an upper lid of an optical module 100H (100) according to an eighth embodiment is removed. In addition, FIG. 12 is a plan view illustrating a state in which an upper lid of an optical module 100I (100) according to a ninth embodiment is removed. As illustrated in FIG. 11, in the optical module 100H, the mirror 10a is provided in the optical isolator 6. In addition, as illustrated in FIG. 12, in the optical module 100I, the mirror 10a is provided in the beam splitter 23. Also with these configurations, the same effects as those of the above-described first embodiment may be obtained.

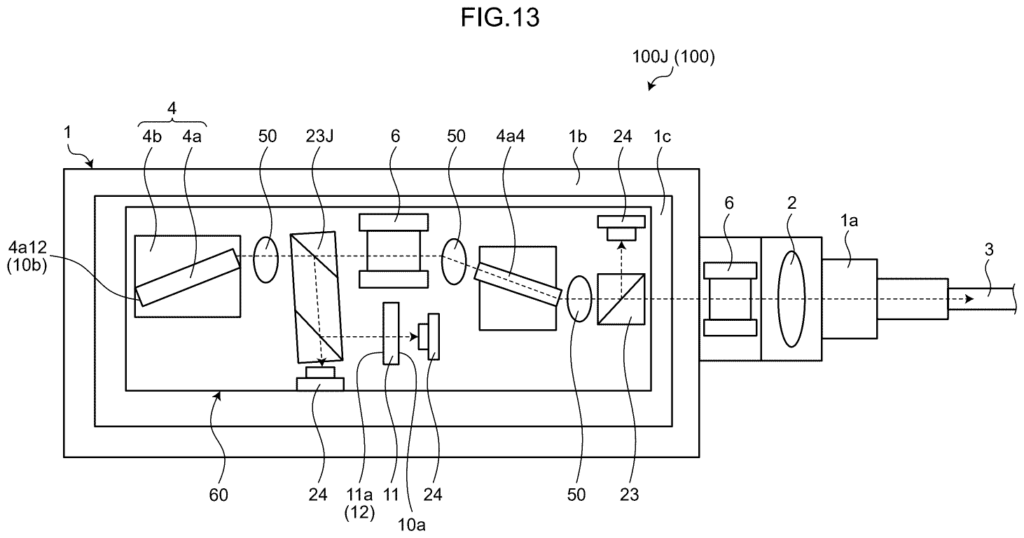

FIG. 13 is a plan view illustrating a state in which an upper lid of an optical module 100J (100) according to a tenth embodiment is removed. The optical module 100J includes a plurality of lenses 50, the beam splitter 23, the SOA 4a4, and the like in addition to the same components as those of the above-described first embodiment. The lens 50 and a beam splitter 23J are interposed between the mirror 10a provided on the end surface of the etalon filter 11 and the mirror 10b provided at the end 4a12 of the light amplification unit 4a1. The heater 12 is provided on the end surface 11a of the etalon filter 11 opposite to the end surface on which the mirror 10a is provided. Also with this configuration, the same effects as those of the above-described first embodiment may be obtained. Note that the heater 12 may be provided on the end surface on which the mirror 10a is provided.

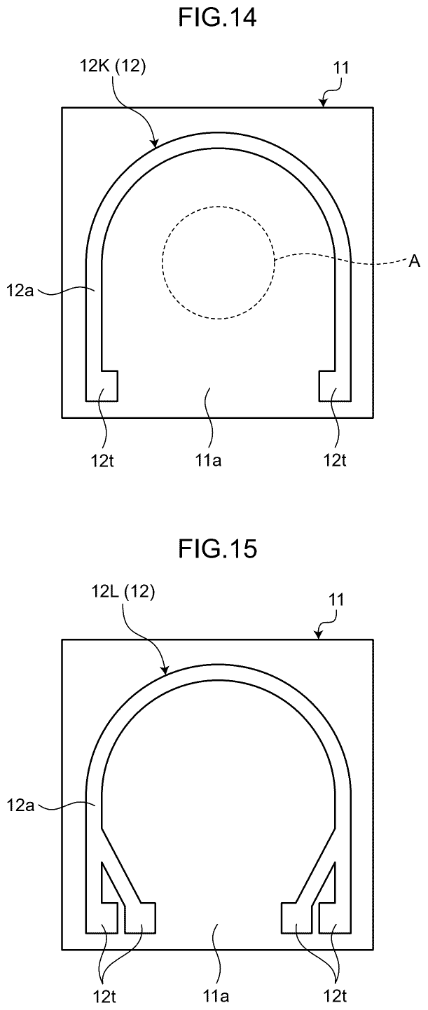

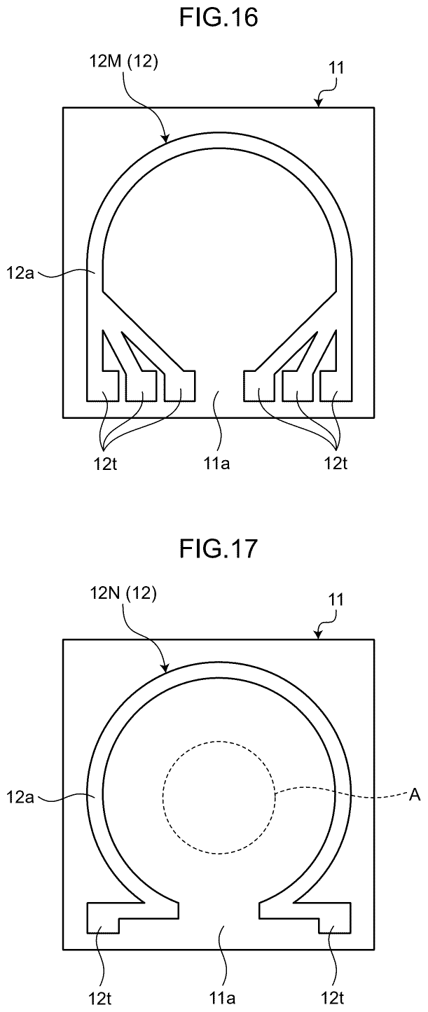

FIGS. 14 to 16 are front views of the etalon filter 11 including heaters 12K to 12M (12) according to eleventh to thirteenth embodiments, respectively. The heaters 12 each include the extending portion 12a extending between the ends 12t and 12t. An intermediate portion of the extending portion 12a is curved along a peripheral edge of the passing region A. In addition, the heater 12K of the eleventh embodiment includes one end 12t on each of both sides across the extending portion 12a, the heater 12L of the twelfth embodiment includes two ends 12t on each of both sides across the extending portion 12a, and the heater 12M of the thirteenth embodiment includes three ends 12t on each of both sides across the extending portion 12a. Also with these configurations, the same effects as those of the above-described first embodiment may be obtained.

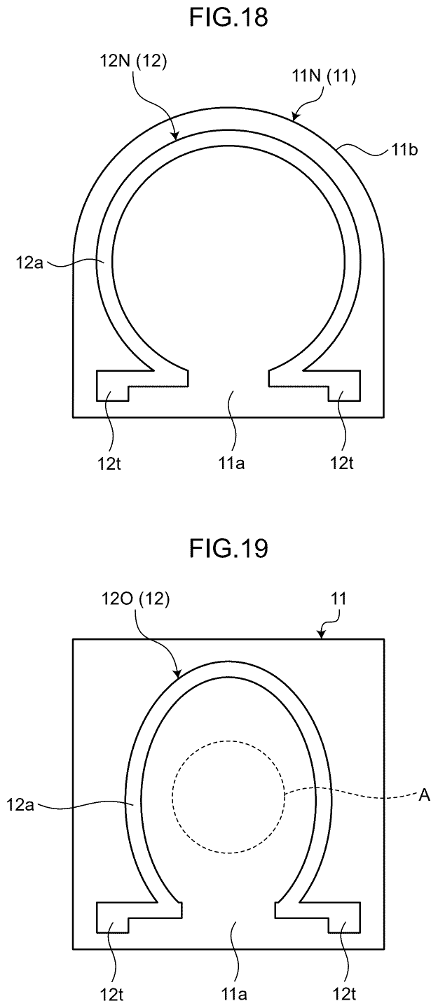

FIGS. 17 to 19 are front views of the etalon filter 11, 11N (11) including heaters 12N to 12O (12) according to fourteenth to sixteenth embodiments, respectively. In these embodiments, the intermediate portion of the extending portion 12a is curved along the peripheral edge of the passing region A in a section longer than that of the above-described eleventh to thirteenth embodiments and has an Q shape. As illustrated in FIG. 18, a side surface 11b of the etalon filter 11N of the fifteenth embodiment has a cylindrical surface shape along the extending portion 12a. In addition, in the fourteenth embodiment and the fifteenth embodiment, the extending portion 12a is curved in an arc shape, whereas in the sixteenth embodiment, the extending portion 12a is curved in an elongated oval shape. Also with these configurations, the same effects as those of the above-described first embodiment may be obtained. In addition, according to these configurations, it is possible to increase the length of the extending portion 12a and thus the heater 12.

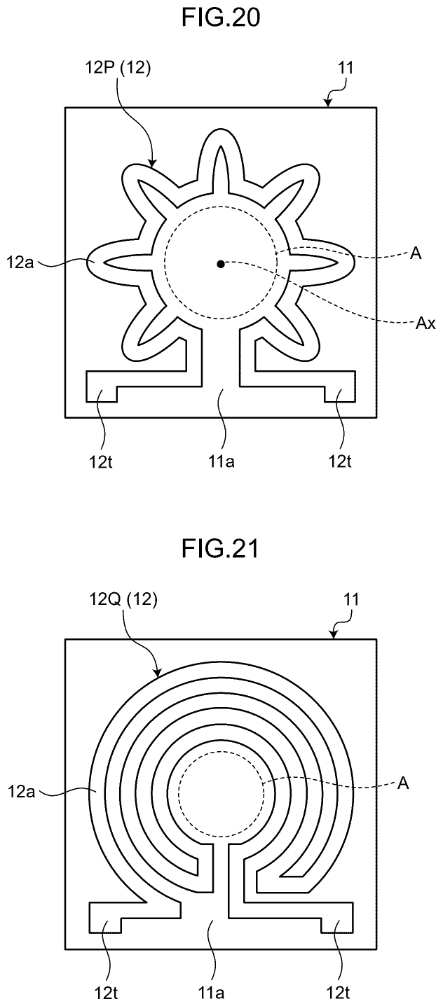

FIG. 20 is a front view of the etalon filter 11 including a heater 12P (12) according to a seventeenth embodiment. In the present embodiment, the extending portion 12a extends along the circumferential direction with respect to an optical axis Ax of light passing through the passing region A while reciprocating in the radial direction. Also with this configuration, the same effects as those of the above-described first embodiment may be obtained. In addition, according to the configuration, it is possible to further increase the length of the extending portion 12a and thus the heater 12.

FIG. 21 is a front view of the etalon filter 11 including a heater 12Q (12) according to an eighteenth embodiment. In the present embodiment, the extending portion 12a extends so as to partially and multiply surround the passing region A. Also with this configuration, the same effects as those of the above-described first embodiment may be obtained. In addition, according to the configuration, it is possible to further increase the length of the extending portion 12a and thus the heater 12.

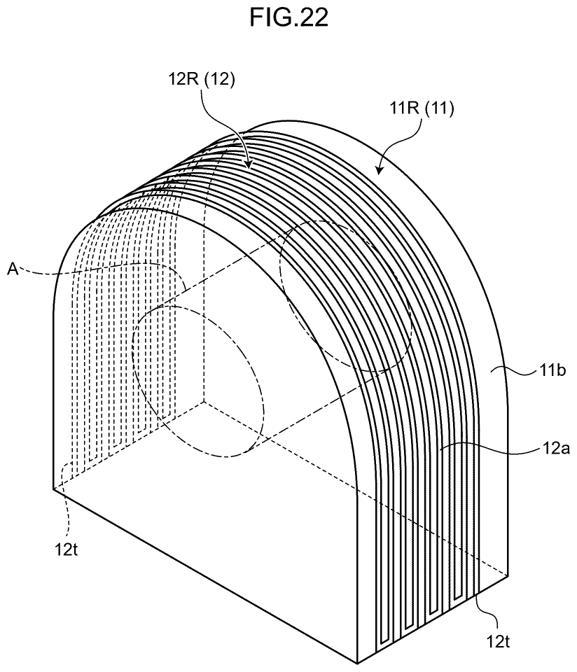

FIG. 22 is a perspective view of an etalon filter 11R (11) including a heater 12R (12) according to a nineteenth embodiment. In the present embodiment, the heater 12R is provided not on the end surface 11a of the etalon filter 11 but on the side surface 11b as a surface through which light does not pass. The side surface 11b is a curved surface having a convex surface portion of a cylindrical surface shape. The heater 12R extends so as to partially and multiply surround the passing region A on the side surface 11b. Also with this configuration, the same effects as those of the above-described first embodiment may be obtained. In addition, according to the configuration, it is possible to further increase the length of the extending portion 12a and thus the heater 12.

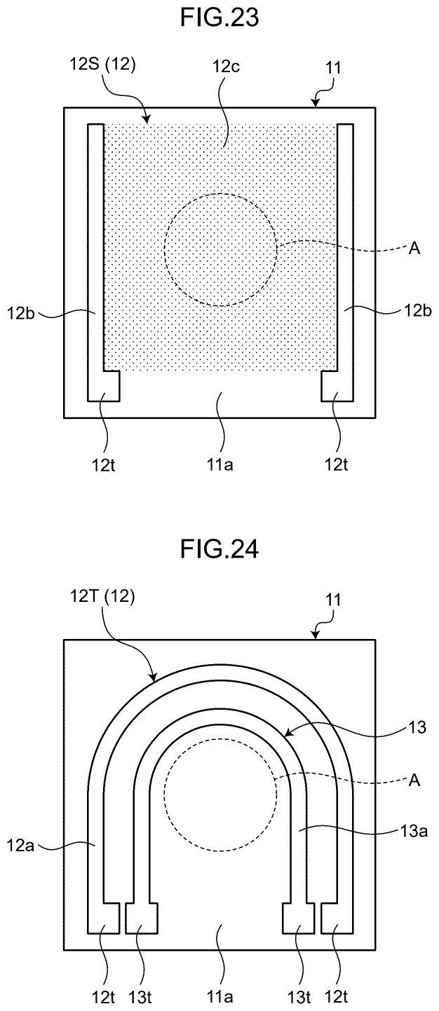

FIG. 23 is a front view of the etalon filter 11 including a heater 12S (12) according to a twentieth embodiment. In the present embodiment, the heater 12S includes two wiring portions 12b separated from each other in the Y direction, and an electric heating portion 12c provided in a state of bridging between the two wiring portions 12b and 12b. The wiring portions 12b each extend in the Z direction from the end 12t with a predetermined width in the Y direction in the vicinity of the ends of the etalon filter 11 in the Y direction and the opposite direction of the Y direction. The electric heating portion 12c has a substantially quadrangular shape and is electrically connected to the two wiring portions 12b and 12b. The electric heating portion 12c is a film made of indium tin oxide (ITO) that generates heat from electric current flow. The electric heating portion 12c has a transmissivity of, for example, 85 [%] or more, and may also be referred to as a transparent conductive film. The electric heating portion 12c is an example of the heater wiring layer. On the other hand, the wiring portion 12b is made of, for example, a stacked structure of Cr/Ni, and is stacked on the electric heating portion 12c, for example. The wiring portion 12b and the electric heating portion 12c are formed by, for example, vapor deposition, sputtering, or the like. In this configuration, the passing region A is set in the substantially transparent electric heating portion 12c. That is, laser light passes through the electric heating portion 12c. On the other hand, since the two wiring portions 12b and 12b are opaque, they do not overlap the passing region A and are provided so as to be outside the passing region A. According to the present embodiment, since the passing region A may be provided in the electric heating portion 12c heated by electric current flow, and the electric heating portion 12c may be widened, the electric heating portion 12c may be heated more efficiently and more quickly by the passing region A. In addition, since the unevenness of heat generation by the electric heating portion 12c depending on the location of the etalon filter 11 may be reduced, the temperature adjustment of the etalon filter 11 by the heater 12S and thus wavelength control may be performed more accurately. The specifications such as locations and shapes of the wiring portion 12b and the electric heating portion 12c are not limited to the example of FIG. 23, and may be variously changed.

FIG. 24 is a front view of the etalon filter 11 including a heater 12T (12) according to a twenty-first embodiment. In the present embodiment, the heater 12T is provided on an end surface 11r of the etalon filter 11. The heater 12T has substantially the same shape as the heater 12K of the eleventh embodiment. However, in the present embodiment, a resistance temperature-measuring wiring layer 13 is provided at an inner side of the heater 12T, in other words, between the passing region A and the heater 12T. The resistance temperature-measuring wiring layer 13 has two ends 13t and 13t and an extending portion 13a. The extending portion 13a extends while bending with a predetermined width and thickness (height) on the end surface 11a between the two ends 13t and 13t. In the present embodiment, the extending portion 13a extends substantially along the peripheral edge of the passing region A in an inverted U shape opened in the opposite direction of the Z direction. In this configuration, the heater 12T is longer than the resistance temperature-measuring wiring layer 13. The resistance temperature-measuring wiring layer 13 is made of, for example, the Ti/Pt stacked structure.

According to the present embodiment, the same effects as those of the above-described first embodiment may be obtained, and the temperature of the etalon filter 11 may be estimated based on a resistance value of the resistance temperature-measuring wiring layer 13, thus making it possible to further enhancing the control accuracy of the wavelength. In addition, according to this configuration, since the resistance temperature-measuring wiring layer 13 is located closer to the passing region A than the heater 12, it is possible to further enhance the detection accuracy of a temperature of the passing region A and thus the control accuracy of the wavelength. In addition, since the length of the heater 12 may be increased, it is possible to obtain the advantage that the passing region A may be heated more efficiently and more quickly by the heater 12, and thus the control responsiveness of the wavelength may be enhanced. The resistance temperature-measuring wiring layer 13 is an example of a temperature detection unit.

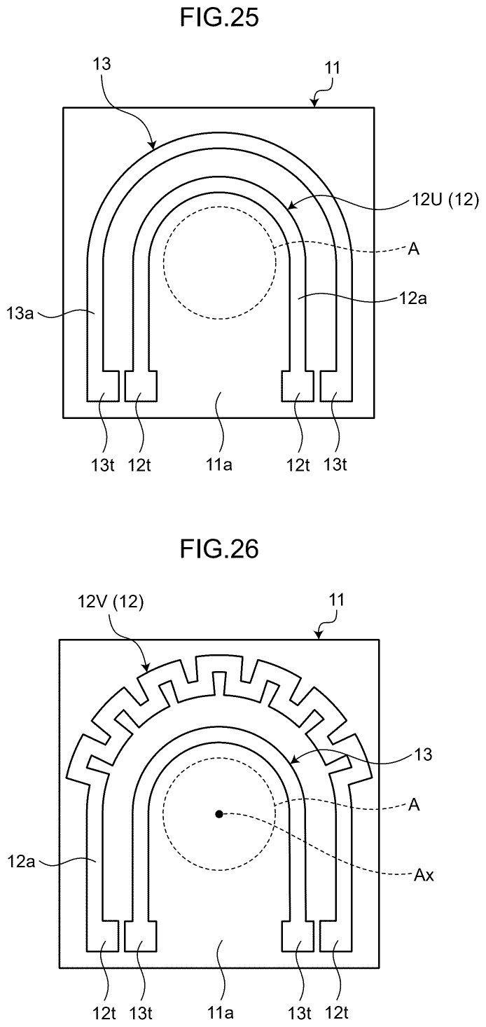

FIG. 25 is a front view of the etalon filter 11 including a heater 12U (12) according to a twenty-second embodiment. The etalon filter 11 of the present embodiment has a configuration in which the heater 12 and the resistance temperature-measuring wiring layer 13 of the twenty-first embodiment switch their locations. That is, in the present embodiment, the heater 12 is provided at an outer side of the resistance temperature-measuring wiring layer 13, in other words, farther from the passing region A than the resistance temperature-measuring wiring layer 13. According to the present embodiment, the same effects as those of the above-described first embodiment may be obtained. In addition, since the heater 12 is located closer to the passing region A than the resistance temperature-measuring wiring layer 13, it is possible to obtain the advantage that the passing region A may be heated more efficiently and more quickly by the heater 12, and thus the control responsiveness of the wavelength may be enhanced.

FIG. 26 is a front view of the etalon filter 11 including a heater 12V (12) according to a twenty-third embodiment. The resistance temperature-measuring wiring layer 13 has substantially the same shape as the resistance temperature-measuring wiring layer 13 (see FIG. 24) of the twenty-first embodiment. However, the shape of the heater 12V is different from the shape of the heater 12T of the twentieth embodiment. Specifically, the extending portion 12a extends along the circumferential direction with respect to the optical axis Ax of the light passing through the passing region A while reciprocating in the radial direction. According to the present embodiment, the same effects as those of the above-described first embodiment may be obtained. According to this configuration, it is possible to further increase the length of the heater 12 because the heater 12 is located at the outer side of the resistance temperature-measuring wiring layer 13 and extends along the circumferential direction while reciprocating in the radial direction. As a result, it is possible to obtain the advantage that the passing region A may be heated more efficiently and more quickly by the heater 12, and thus the control responsiveness of the wavelength may be further enhanced.

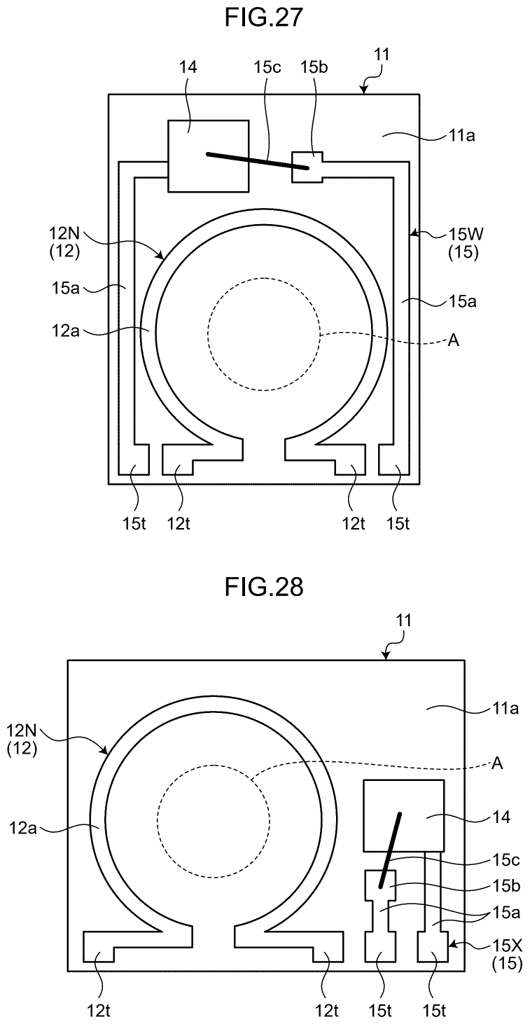

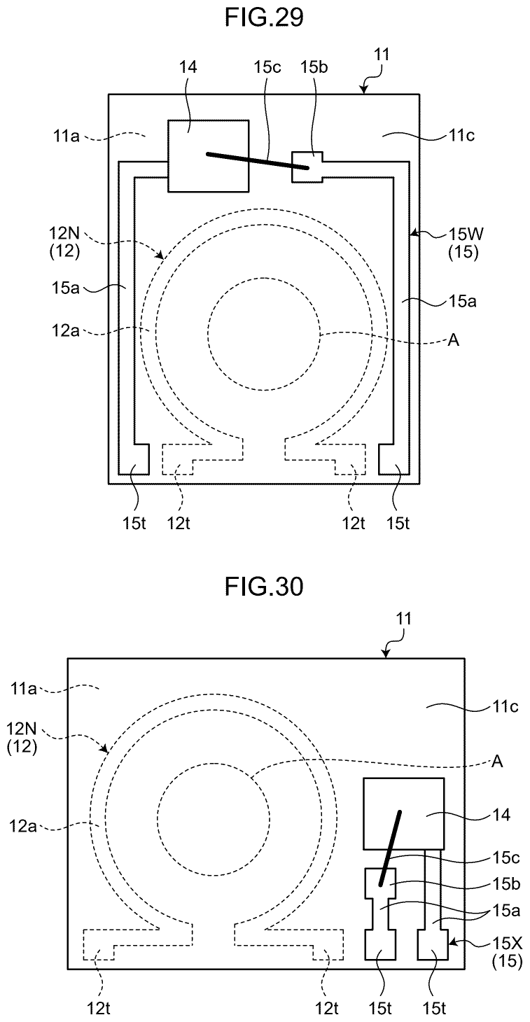

FIGS. 27 and 28 are front views illustrating modifications of the etalon filter 11, and FIGS. 29 to 32 are rear views illustrating modifications of the etalon filter 11. Note that, although each etalon filter 11 illustrated in FIGS. 27 to 32 is provided with the heater 12N (see FIG. 17) having the same configuration as that of the fourteenth embodiment, the present disclosure is not limited thereto, and the heater 12 having another configuration may be provided.

In the examples of FIGS. 27 to 32, the etalon filter 11 is provided with a temperature sensor such as a thermistor 14, for example. Furthermore, each etalon filter 11 is provided with wiring 15 (15W to 15Z) for flowing an electric current through the thermistor 14. The wiring 15 includes, for example, an electrode portion 15t, an extending portion 15a, a pad portion 15b, and a wire portion 15c. In the example of FIG. 27, the thermistor 14 and the wiring 15 form a circuit from the electrode portion 15t on the left side in the drawing to the electrode portion 15t on the right side in the drawing via the extending portion 15a, a pad portion (not illustrated) to which the thermistor 14 is electrically connected, the thermistor 14, the wire portion 15c, the pad portion 15b, and the extending portion 15a in this order. According to this configuration, for example, it is possible to estimate the temperature at the location where the thermistor 14 is provided and thus the temperature of the passing region A from a detection value such as a potential difference between the two electrode portions 15t or a resistance value based on the potential difference. In this case, for the temperature adjustment of the etalon filter 11 using the heater 12, feedback control based on the detection value may be performed. Also in the examples of FIGS. 28 to 32, the same circuit is configured and the same detection and control may be performed. The thermistor 14 as the temperature sensor is an example of the temperature detection unit.

In the examples of FIGS. 27 and 28, the thermistor 14 and the wiring 15 are provided on the end surface 11a on which the heater 12 is provided. On the other hand, in the examples of FIGS. 29 to 32, the thermistor 14 and the wiring 15 are provided on an end surface 11c on the opposite side from the end surface 11a on which the heater 12 is provided. The end surfaces 11a and 11c are examples of the surface. Note that, when the end surface 11a is referred to as the surface, the end surface 11c may also be referred to as a back surface. In addition, the thermistor 14 and the wiring 15 may be provided on the side surface 11b of the etalon filter 11. In this case, the side surface 11b is an example of the surface.

As illustrated in FIGS. 27 to 32, the thermistor 14 and the wiring 15 may be arranged in various layouts.

In the examples of FIGS. 27 and 29, although the surfaces (end surfaces 11a and 11c) on which the thermistor 14 and the wiring 15 are provided are different, the arrangement of the thermistor 14 and the wiring 15 on each surface is substantially the same. In these examples, the circuits including the thermistor 14 and the wiring 15 are arranged so as to surround the passing region A and the outer side of the heater 12 in a plan view when viewed in a direction orthogonal to the end surfaces 11a and 11c.

In the examples of FIGS. 28 and 30, although the surfaces (end surfaces 11a and 11c) on which the thermistor 14 and the wiring 15 are provided are different, the arrangement of the thermistor 14 and the wiring 15 on each surface is substantially the same. In these examples, the circuits including the thermistor 14 and the wiring 15 are provided at a location away from the passing region A and the heater 12 without surrounding the heater 12 in the plan view when viewed in the direction orthogonal to the end surfaces 11a and 11c.

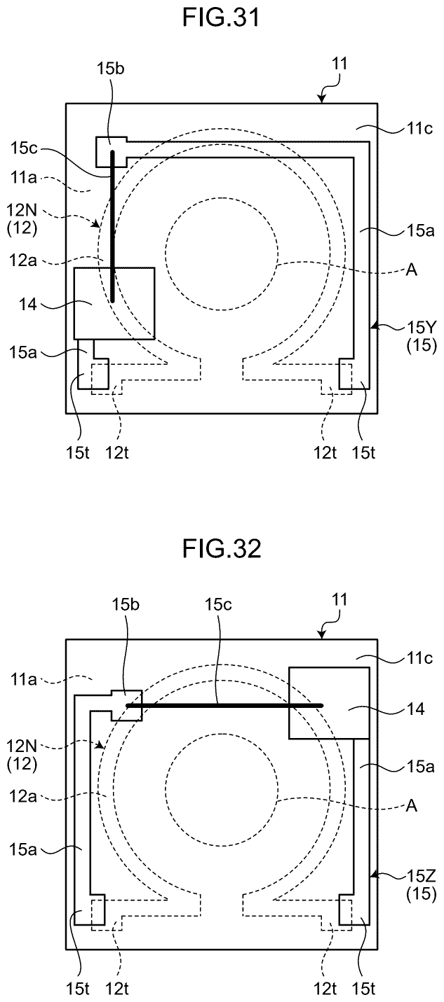

In the examples of FIGS. 27 to 30, the circuits including the thermistor 14 and the wiring 15 are arranged so as not to overlap the heater 12 in the plan view when viewed in the direction orthogonal to the end surfaces 11a and 11c. On the other hand, in the examples of FIGS. 31 and 32, the circuit is arranged so as to partially overlap the heater 12 in the plan view. According to the examples of FIGS. 31 and 32, the thermistor 14 may detect the temperature at a location closer to the passing region A than the location in the example of FIGS. 27 to 30. According to the examples of FIGS. 31 and 32, it is possible to obtain the advantages that the etalon filter 11 may be configured more compactly and that the temperature of the passing region A may be detected more accurately, thus making it possible to enhance the control accuracy.

Also in the modifications of FIGS. 27 to 32, the same effects as those of each of the above-described embodiments may be obtained.

According to the present disclosure, it is possible to obtain, for example, the improved novel optical device and the wavelength-tunable laser capable of adjusting the temperature of the optical filter separately and more accurately.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An optical device comprising:
a base;
a plurality of optical components fixed to the base, the plurality of optical components including an etalon filter; and
a heater wiring layer provided at a location away from a light passing region on a surface of the etalon filter and configured to generate heat from electric current flow.

2. The optical device according to claim 1, wherein the heater wiring layer is provided on an end surface as the surface through which the light passes.

3. The optical device according to claim 1, wherein the heater wiring layer is provided on a side surface as the surface through which the light does not pass.

4. The optical device according to claim 1, wherein the heater wiring layer extends so as to at least partially surround the passing region.

5. The optical device according to claim 1, wherein the etalon filter includes a body and a reflecting film provided at an incident end and an emission end of the body, and
the body is made of glass or silicon.

6. The optical device according to claim 1, wherein the heater wiring layer has a stacked structure made of one or more of Ti, Pt, Au, Ni, Ta2N, TiW and indium tin oxide, or a material containing any one or more of Ti, Pt, Au, Ni, Ta2N, TiW and indium tin oxide.

7. The optical device according to claim 1, wherein the heater wiring layer is configured to detect temperature.

8. The optical device according to claim 7, wherein the heater wiring layer includes a stacked structure of Ti/Pt.

9. The optical device according to claim 1, wherein the heater wiring layer is configured to change a temperature of a light passing region of the etalon filter in a range of room temperature or more and 150° C. or less by changing supplied power.

10. The optical device according to claim 1, where in the plurality of optical components include a plurality of etalon filters each provided with the heater wiring layer.

11. The optical device according to claim 1, further comprising a temperature detection unit provided on the surface of the etalon filter.

12. The optical device according to claim 11, wherein the temperature detection unit is a resistance temperature-measuring wiring layer in which a resistance value changes according to a temperature change.

13. The optical device according to claim 12, wherein the resistance temperature-measuring wiring layer is located closer to the passing region than the heater wiring layer.

14. The optical device according to claim 12, wherein the heater wiring layer is longer than the resistance temperature-measuring wiring layer.

15. The optical device according to claim 12, wherein the resistance temperature-measuring wiring layer is located farther from the passing region than the heater wiring layer.

16. The optical device according to claim 1, wherein the heater wiring layer extends along a circumferential direction with respect to an optical axis of light passing through the passing region while reciprocating in a radial direction.

17. The optical device according to claim 1, wherein the heater wiring layer extends so as to at least partially and multiply surround the passing region.

18. A wavelength-tunable laser comprising:
a light amplification unit configured to generate and amplify light and output the light from a first end and a second end on an opposite side from the first end;
a first mirror configured to reflect the light output from the first end;
a second mirror configured to reflect the light output from the second end;
an etalon filter provided between the light amplification unit and the first mirror or the second mirror, the etalon filter having a predetermined wavelength characteristic and being configured to allow the light output from the light amplification unit to pass therethrough; and
a heater wiring layer provided at a location away from a light passing region on a surface of the etalon filter and configured to generate heat from electric current flow.

19. The wavelength-tunable laser according to claim 18, further comprising a lens provided between the light amplification unit and the etalon filter and configured to allow the light traveling between the light amplification unit and the etalon filter to pass therethrough.

20. The wavelength-tunable laser according to claim 18, further comprising
a temperature adjuster configured to adjust a temperature of the light amplification unit; and
a heat shield interposed between the temperature adjuster and the etalon filter and configured to suppress heat conduction between the temperature adjuster and the etalon filter.
